(19) United States
(12) Patent Application Publication
(10) Pub. No.: US 2021/0313417 A1
(43) Pub. Date: Oct. 7, 2021

(54) Radio frequency (RF) integrated power-conditioning capacitor

(71) Applicant: 3D GLASS SOLUTIONS, INC., Albuquerque, NM (US)

(72) Inventors: Jeb H. Flemming, Albuquerque, NM (US); Jeff A. Bullington, Orlando, FL (US)

(21) Appl. No.: 17/348,378

(22) Filed: Jun. 15, 2021

Related U.S. Application Data
(63) Continuation-in-part of application No. 16/482,889, filed on Aug. 1, 2019, now Pat. No. 11,076,489.
(60) Provisional application No. 62/655,618, filed on Apr. 10, 2018.

(51) Int. Cl. H01L 49/02; H01G 4/33; H01G 4/12; H01G 9/00

(52) U.S. Cl. CPC H01L 28/75; H01G 9/0029; H01G 4/129; H01G 4/33

(57) ABSTRACT

A method of making capacitive device in or on a photodefinable glass substrate comprising: a first electrode comprising: one or more copper columns each with patterned or textured surfaces; and one or more rows of a Resistor Inductor Diode (RLD) in contact with the one or more copper columns, wherein the one or more rows of the RLD are tied together in parallel;

a dielectric material in contact with the one or more copper columns and in contact with the one or more rows of the RLD; and a second electrode comprising: one or more copper columns each with patterned or textured surfaces; and one or more rows or columns of the RLD in contact with the one or more copper columns, wherein the one or more rows or columns of the RLD are tied together in parallel.

### CROSS-REFERENCE TO RELATED APPLICATIONS

This application is a continuation of U.S. patent application Ser. No. 16/482,889 filed on Aug. 1, 2019, now U.S. Pat. No. ______ issued on ______, 2021, which is a 371 National Phase Application of PCT International Patent Application No. PCT/US2019/024496 filed on Mar. 28, 2019, which claims priority to U.S. Provisional Patent Application Ser. No. 62/655,618 filed Apr. 10, 2018, the contents of which is incorporated by reference herein in its entirety.

### TECHNICAL FIELD OF THE INVENTION

The present invention relates to creating an integrated radio frequency (RF) power conditioning capacitor.

### BACKGROUND OF THE INVENTION

Without limiting the scope of the invention, its background is described in connection with power-conditioning capacitors.

Recent RF devices operate at relatively high power. This class of RF devices produces pulses at voltages greater that 10 V and at currents greater than 2 A. Switching the signal on and off at this level of current and voltage creates significant harmonic signals. These harmonic signals can disrupt the operation of the circuit. Large-value integrated silicon-based capacitors fail to achieve the required capacitance to perform power conditioning to suppress the harmonic signals, and they suffer from dielectric breakdown.

### SUMMARY OF THE INVENTION

The present inventors have developed integrated photodefinable glass-ceramics that can be converted from a glass phase to a ceramic phase through a combination of ultraviolet light exposure and thermal treatments. The selective application of the ultraviolet light exposure using a photo mask or shadow mask creates regions of ceramic material in the photodefinable glass. The present invention includes a method to fabricate one or more two- or three-dimensional capacitive devices that can be used to perform, among other functions, power conditioning to suppress disruptive harmonic signals in RF devices that produce pulses at voltages greater than 10 V and at greater than 2 A by preparing a photosensitive glass substrate (also known as a photodefinable glass substrate, with “photosensitive” and “photodefinable” being interchangeable terms herein) with high-surface-area structures, dielectric material, and one or more metals.

In one embodiment of the present invention, a method of making an integrated large capacitance in a small form factor for power conditioning on a photodefinable glass includes:

depositing a conductive seed layer on a photodefinable glass processed to form one or more via openings in the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; depositing a dielectric layer on or around the posts; metal coating the dielectric layer to form a second electrode; connecting a first metal layer to all of the first electrodes in parallel to form a single electrode for a capacitor; and connecting a second metal layer to all of the second electrodes in parallel to form a second electrode for the capacitor. In one aspect, the dielectric layer is a thin film between 0.5 nm and 1000 nm thick. In another aspect, the dielectric layer is a sintered paste between 0.05 μm and 100 μm thick. In another aspect, the dielectric layer has an electrical permittivity between 10 and 10,000. In another aspect, the dielectric layer has an electrical permittivity between 2 and 100. In another aspect, the dielectric layer is deposited by ALD. In another aspect, the dielectric layer is deposited by doctor blading. In another aspect, the capacitor has a capacitance density greater than 1,000 pf/mm².

In another embodiment of the present invention, a method of making an integrated large capacitance in a small form factor for power conditioning on a photodefinable glass substrate includes: masking a circular pattern on the photosensitive glass substrate; exposing at least one portion of the photosensitive glass substrate to an activating UV energy source; heating the photosensitive glass substrate to a heating phase of at least ten minutes above its glass transition temperature; cooling the photosensitive glass substrate to transform at least part of the exposed glass to a crystalline material to form a glass—ceramic crystalline substrate; partially etching away the ceramic phase of the photodefinable glass substrate with an etchant solution; depositing a conductive seed layer on the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; depositing a dielectric layer on or around the posts; metal coating the dielectric layer to form a second electrode; connecting a first metal layer to all of the first electrodes in parallel to form a single electrode for a capacitor; and connecting a second metal layer to all of the second electrodes in parallel to form a second electrode for a capacitor. In one aspect, the dielectric layer is a thin film between 0.5 nm and 1000 nm thick. In another aspect, the dielectric layer is a sintered paste between 0.05 μm and 100 μm thick. In another aspect, the dielectric layer has an electrical permittivity between 10 and 10,000. In another aspect, the dielectric layer has an electrical permittivity between 2 and 100. In another aspect, the dielectric layer is deposited by ALD. In another aspect, the dielectric layer is deposited by doctor blading. In another aspect, the capacitor has a capacitance density greater than 1,000 pf/mm².

Yet another embodiment of the present invention includes an integrated capacitor made by a method including: masking a circular pattern on a photosensitive glass substrate; exposing at least one portion of the photosensitive glass substrate to an activating UV energy source; heating the photosensitive glass substrate to a heating phase of at least ten minutes above its glass transition temperature; cooling the photosensitive glass substrate to transform at least part of the exposed glass to a crystalline material to form a glass—ceramic crystalline substrate; partially etching away the ceramic phase of the photodefinable glass substrate with an etchant solution; depositing a conductive seed layer on the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; depositing a dielectric layer on or around the posts; metal coating the dielectric layer to form a second electrode; connecting a first metal layer to all of the first electrodes in parallel to form a single electrode for a capacitor; and connecting a second metal layer to all of the second electrodes in parallel to form a second electrode for the capacitor. In one aspect, the dielectric layer is a thin film between 0.5 nm and 1000 nm thick. In another aspect, the dielectric layer is a sintered paste between 0.05 μm and 100 μm thick. In another aspect, the dielectric material has an electrical permittivity between 10 and 10,000. In another aspect, the dielectric thin film has an electrical permittivity between 2 and 100. In another aspect, the dielectric thin film material is deposited by ALD. In another aspect, the dielectric paste material is deposited by doctor blading. In another aspect, the capacitor has a capacitance density greater than 1,000 pf/mm².

Yet another embodiment includes a method of making a capacitive device, the method including providing a photodefinable glass substrate; processing the photodefinable glass substrate to form one or more vias; rinsing the one or more vias with an etchant to pattern or texture walls of the one or more vias, increasing the surface areas of the walls; depositing a metallized seed layer on the photodefinable glass substrate, wherein the metallized seed layer is deposited in the one or more vias; depositing a copper layer on the seed layer, wherein the copper layer is deposited in the one or more vias; exposing the photodefinable glass substrate by removing the seed layer and the copper layer from a first surface of the photodefinable glass substrate and from a second surface of the photodefinable glass substrate, leaving the seed layer and the copper layer in the one or more vias; making one or more rectangular wells in each of the first surface and the second surface around the one or more vias, exposing the copper layer in the one or more vias as copper columns; electroplating a flash coating of (1) a non-oxidizing metal, (2) a first metal that forms a semiconductor oxide or (3) a second metal that forms a conductive oxide on the first surface and the second surface of the photodefinable glass substrate; depositing a dielectric material on the front surface and the back surface of the photodefinable glass substrate; filling the one or more rectangular wells with an RLD; heating the photodefinable glass substrate; forming the RLD on the first surface of the photodefinable glass substrate into rows and tying the rows together in parallel to form a first capacitor electrode; and forming the RLD on the second surface of the photodefinable glass substrate into rows or columns and tying the rows or columns together in parallel to form a second capacitor electrode. In one aspect of this method, the step of depositing the metallized seed layer on the photodefinable glass substrate is performed with a chemical vapor deposition process. In another aspect, the metalized seed layer includes titanium. In another aspect, a thickness of the metalized seed layer is greater than 50 nm and less than 1000 nm. In another aspect, a thickness of the metalized seed layer is 150 nm. In another aspect, the step of depositing the copper layer on the metalized seed layer is performed by placing the photodefinable glass substrate in an electroplating bath. In another aspect, a thickness of the copper layer is 25 μm. In another aspect, the step of exposing the photodefinable glass substrate by removing the seed layer and the copper layer is performed by lapping, by polishing, or by both lapping and polishing. In another aspect, the step of making one or more rectangular wells in each of the first surface and the second surface around the one or more vias includes: converting one or more portions of the photodefinable glass substrate to a crystalline ceramic; and etching the crystalline ceramic away. In another aspect, this method further includes contacting the back surface of the photodefinable glass substrate, including the copper layer left in the one or more vias, with a metalized polyimide, performed after the step of making one or more rectangular wells and before the step of electroplating a flash coating on the front surface and the back surface of the photodefinable glass substrate. In another aspect, the step of electroplating a flash coating on the front surface and the back surface of the photodefinable glass substrate includes electroplating a flash coating of gold. In another aspect, the step of depositing the dielectric material is performed using atomic layer deposition. In another step, the dielectric material includes (1) a vapor-phase dielectric, (2) a paste, or (3) some combination. In another step, the dielectric material includes Ta₂O₅, Al₂O₃, a BaTiO₃ paste, or some combination. In another step, a thickness of the layer of dielectric material is greater than or equal to 1 nm and less than or equal to 1000 nm. In another aspect, a thickness of the layer of dielectric material is 5 nm. In another aspect, the RLD includes a copper paste. In another aspect, the step of depositing the RLD is performed by a process of silk-screening. In another aspect, the step of heating the photodefinable glass substrate includes heating to 450° C. to 700° C. for 5 to 60 minutes in an inert gas, vacuum environment, or oxygen environment.

Yet another embodiment includes a capacitive device made by the method of including providing a photodefinable glass substrate; processing the photodefinable glass substrate to form one or more vias; rinsing the one or more vias with an etchant to pattern or texture walls of the one or more vias, increasing the surface areas of the walls; depositing a metallized seed layer on the photodefinable glass substrate, wherein the metallized seed layer is deposited in the one or more vias; depositing a copper layer on the seed layer, wherein the copper layer is deposited in the one or more vias; exposing the photodefinable glass substrate by removing the seed layer and the copper layer from a first surface of the photodefinable glass substrate and from a second surface of the photodefinable glass substrate, leaving the seed layer and the copper layer in the one or more vias; making one or more rectangular wells in each of the first surface and the second surface around the one or more vias, exposing the copper layer in the one or more vias as copper columns; electroplating a flash coating of (1) a non-oxidizing metal, (2) a first metal that forms a semiconductor oxide or (3) a second metal that forms a conductive oxide on the first surface and the second surface of the photodefinable glass substrate; depositing a dielectric material on the front surface and the back surface of the photodefinable glass substrate; filling the one or more rectangular wells with an RLD; heating the photodefinable glass substrate; forming the RLD on the first surface of the photodefinable glass substrate into rows and tying the rows together in parallel to form a first capacitor electrode; and forming the RLD on the second surface of the photodefinable glass substrate into rows or columns and tying the rows or columns together in parallel to form a second capacitor electrode.

Yet another embodiment includes a capacitive device including a first electrode including: one or more first copper columns each with patterned or textured surfaces to increase surface areas of the surfaces; and one or more rows of an RLD in contact with the one or more first copper columns, wherein the one or more rows of the RLD are tied together in parallel; a dielectric material in contact with the one or more first copper columns and in contact with the one or more rows of the RLD; and a second electrode including: one or more second copper columns each with patterned or textured surfaces to increase surface areas of the surfaces; and one or more rows or columns of the RLD in contact with the one or more second copper columns, wherein the one or more rows or columns of the RLD are tied together in parallel; wherein the capacitive device is in or on a photodefinable glass substrate. In one aspect of this capacitive device, a thickness of the copper layer is 25 μm. In another aspect, the dielectric material includes (1) a vapor-phase dielectric, (2) a paste, or (3) some combination. In another aspect, the dielectric material includes Ta₂O₅, Al₂O₃, a BaTiO₃ paste, or some combination. In another aspect, a thickness of the layer of dielectric material is greater than or equal to 1 nm and less than or equal to 1000 nm. In another aspect, a thickness of the layer of dielectric material is 5 nm. In another aspect, the RLD includes a copper paste.

### BRIEF DESCRIPTION OF THE DRAWINGS

For a more complete understanding of the features and advantages of the present invention, reference is now made to the detailed description of the invention along with the accompanying figures and in which:

FIG. 1 shows the image of through-hole vias filled with electroplated copper with an underlying seed layer.

FIG. 2A shows a cross section of the RF power conditioning capacitor and the materials key where the dielectric material is HfO₂.

FIG. 2B shows a top view of the RF power conditioning capacitor.

FIG. 3 shows a Side View of a BaTiO₃-based integrated power condition capacitor.

FIG. 4 shows a through-hole via with a 65 μm diameter and a 72 μm center-to-center pitch.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below.

Terms defined herein have meanings as commonly understood by a person of ordinary skill in the areas relevant to the present invention. Terms such as “a”, “an” and “the” are not intended to refer to only a singular entity, but they are intended to include the general class of which a specific example may be used for illustration. The terminology herein is used to describe specific embodiments of the invention, but their usage does not limit the invention, except as outlined in the claims.

Photodefinable glass materials are processed using first-generation semiconductor equipment in a simple three-step process where the final material can be fashioned into either glass or ceramic or can contain regions of both glass and ceramic. Photodefinable glass has several advantages for the fabrication of a wide variety of microsystems components, systems on a chip, and systems in a package. Microstructures and electronic components have been produced relatively inexpensively with these types of glass using conventional semiconductor and printed circuit board (PCB) processing equipment. In general, glass has high temperature stability, good mechanical and electrically properties, and a better chemical resistance than plastics and many types of metals.

When exposed to UV-light within the absorption band of cerium oxide, the cerium oxide acts as a sensitizer by absorbing a photon and losing an electron. This reaction reduces neighboring silver oxide to form silver atoms, e.g.,

Ce³⁺+Ag⁺Ce⁴⁺+Ag⁰

The silver ions coalesce into silver nanoclusters during the heat treatment process and induce nucleation sites for the formation of a crystalline ceramic phase in the surrounding glass. This heat treatment must be performed at a temperature near the glass-transformation temperature. The ceramic crystalline phase is more soluble in etchants, such as hydrofluoric acid (HF), than the unexposed vitreous, amorphous glassy regions. In particular, the crystalline ceramic regions of FOTURAN® are etched about 20 times faster than the amorphous regions in 10% HF, enabling microstructures with wall-slope ratios of about 20:1 when the exposed regions are removed. See T. R. Dietrich et al., “Fabrication technologies for microsystems utilizing photoetchable glass,” Microelectronic Engineering 30, 497 (1996), which is incorporated herein by reference. Other compositions of photodefinable glass will etch at different rates.

One method of fabricating a capacitive device using a photodefinable glass substrate comprising silica, lithium oxide, aluminum oxide and cerium oxide involves the use of a mask and UV light to create a pattern with one or more two-dimensional or three-dimensional structures within the photodefinable glass substrate.

The capacitive device is formed by making a series of connected structures in the photodefinable glass substrate. The structures can be rectangular, circular, elliptical, fractal, or of other shapes that provide capacitance. The patterned regions of a photodefinable glass known as APEX® glass can be filled with metal, alloys, composites, glass, or other media by a number of methods, including but not limited to plating or vapor-phase deposition. The electrical permittivity of the media combined with the dimensions, high surface area, and number of structures in the device provide the capacitance of the device. Depending on the frequency of operation, the capacitive device design will require materials of different permittivity, so at higher-frequency operations a material such as copper or another similar material is the media of choice for capacitive devices. Once the capacitive device has been made, the supporting APEX® glass can be left in place or removed to create an array of capacitive structures that can be connected in series or in parallel.

This process can be used to create a large-surface-area capacitor that will exceed the desired technical requirements for an integrated power conditioning capacitance device, with values of greater than or equal to 1 nf per mm². There are different device architectures based on the relative permittivity used and the preferred deposition technique for the dielectric material. The present invention provides a method to create a device architecture for each dielectric material.

Generally, glass-ceramic materials have had limited success in microstructure formation because they are plagued by issues of performance, uniformity, usability by others, and availability. Past glass-ceramic materials have yielded an etch aspect-ratio of approximately 15:1. In contrast, APEX® glass has an average etch aspect ratio greater than 50:1. This allows users to create smaller and deeper features. Additionally, our manufacturing process enables product yields of greater than 90%, where legacyglass yields are closer to 50%. Lastly, in legacy glass-ceramics, only about 30% of the glass is converted into the ceramic state, whereas with APEX® glass this conversion is closer to 70%.

The composition of APEX® glass provides three main mechanisms for its enhanced performance: (1) the higher amount of silver leads to the formation of smaller ceramic crystals, which are etched faster at the grain boundaries, (2) the decrease in silica content (the main constituent etched by the HF acid) decreases the undesired etching of unexposed material, and (3) the higher total weight percent of the alkali metals and boron oxide produces a much more homogeneous glass during manufacturing.

Ceramicization of APEX® glass is accomplished by exposing the entire glass substrate to approximately 20 J/cm² of 310-nm light. When trying to create glass spaces within the ceramic, users expose the material except where the glass is to remain glass.

Previous high-surface-area capacitors demonstrated by the inventors use thin-film-metalized vias produced using a chemical vapor deposition (CVD) process. The metalized vias are then coated with a thin film of dielectric material such as a 20-nm layer of Al₂O₃ using an atomic layer deposition (ALD) process. Then a top metallization is applied to make a large capacitance due to the effect of the surface areas of the vias and the ultra-thin dielectric.

The present invention includes a method for fabricating a capacitive device in or on a photodefinable glass substrate for electrical microwave and RF applications. The photodefinable glass substrate may have a wide variety of compositional variations, including but not limited to: 60 to 76 weight % silica; at least 3 weight % K₂O with 6 to 16 weight % of a combination of K₂O and Na₂O; 0.003 to 1 weight % of at least one oxide selected from the group consisting of Ag2O and Au2O; 0.003 to 2 weight % Cu₂O; 0.75 to 7 weight % B2O3, and 6 to 7 weight % Al₂O₃; with the combination of B₂O₃; Al₂O₃ not exceeding 13 weight %; 8 to 15 weight % Li₂O; and 0.001 to 0.1 weight % CeO₂. Photodefinable glasses having this composition and other varied compositions are generally referred to as the APEX® glass.

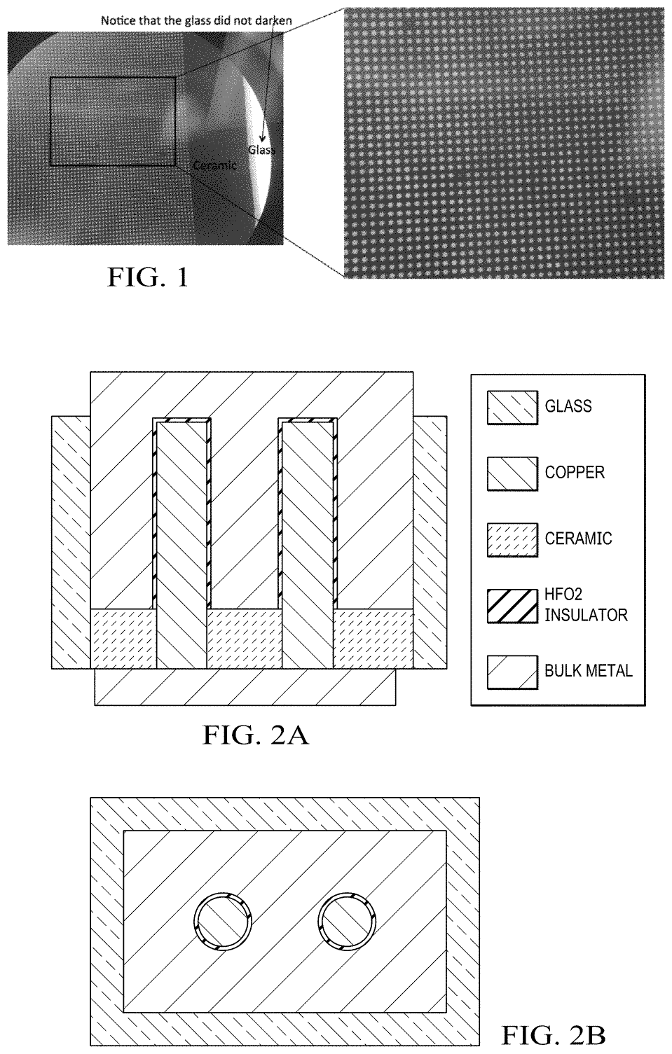

The exposed portion of the photodefinable glass substrate may be transformed into a crystalline ceramic material by heating the glass substrate to a temperature near the glass-transformation temperature. When etching the transformed photodefinable glass substrate in an etchant such as hydrofluoric acid, the anisotropic-etch ratio of the exposed portion to the unexposed portion is at least 30:1 when the glass is exposed to a broad spectrum mid-ultraviolet (about 308 to 312 nm) flood lamp to provide a shaped glass structure that has an aspect ratio of at least 30:1 and to create a capacitive structure. The mask for the exposure can be a halftone mask that provides a continuous grey scale to the exposure to form a curved structure for the creation of a capacitive structure or device. A digital mask can also be used with the exposure to produce a capacitive structure or device. The exposed glass substrate is then baked, typically in a two-step process. First, the exposed glass is heated at 420° C. to 520° C. for 10 minutes to 2 hours, for the coalescing of silver ions into silver nanoparticles. Second, the exposed glass is heated at 520° C. to 620° C. for 10 minutes to 2 hours, allowing the lithium oxide to form around the silver nanoparticles. The baked glass substrate is then etched in an etchant of HF solution, typically 5% to 10% by volume, wherein the etch ratio of the exposed portion to the unexposed portion is at least 30:1 when exposed with a broad spectrum mid-ultraviolet flood light, and greater than 30:1 when exposed with a laser, to provide a shaped glass structure with an anisotropic-etch ratio of at least 30:1. FIG. 1 shows the image of through-hole vias with an underlying seed layer.

One embodiment is shown in FIGS. 2A and 2B. This embodiment includes one or more two- or three-dimensional capacitive devices created with one or more metal columns in a photodefinable glass substrate. The photodefinable glass substrate is then patterned with a pattern and etched through the volume of the substrate. The pattern may be rectangular, circular, elliptical, fractal, or of other shapes that provide capacitance. A uniform metallized seed layer, preferably including titanium, is deposited across the substrate, including the vias, by a CVD process. The seed-layer thickness can range from 50 nm to 1000 nm but is preferably 150 nm. The substrate is then placed into an electroplating bath where copper (Cu) is deposited on the seed layer. The copper layer needs to be sufficiently thick to fill the vias, in this case 25 μm. The copper layer and the seed layer are then removed from a first surface and a second surface of the wafer, e.g., by lapping and polishing or both, back to the photodefinable glass substrate. This can be seen in FIG. 2A. One or more rectangular wells are made in the first and second surfaces of the photodefinable glass substrate using the process described herein to convert 10% to 90% of the volume of the substrate, preferably 80%, to a crystalline ceramic and to etch these crystalline ceramic volumes away. The vias may also receive an additional low-concentration rinse with an etchant such as dilute HF. The low-concentration rinse will pattern or texture the ceramic walls of the vias. The patterning or texturing of the ceramic walls significantly increases the surface area of the one or more capacitive devices, directly increasing the capacitance of the devices. Next, the first surface, the second surface, or both the first and second surfaces of the photodefinable glass substrate with the one or more exposed copper columns are placed in contact with a metalized polyimide. The metallization of the polyimide allows for electrical connection without shorting out other elements. The photodefinable glass substrate with the exposed copper columns contacted with the metalized polyimide is placed into an electroplating bath where a flash coating of non-oxidizing metal or a metal that forms a semiconductor oxide or a conductive oxide is electroplated on the surfaces of the copper columns. The metal electroplated on the surfaces of the copper columns is preferably gold (Au). This flash coating prevents the oxidation of the copper columns during the deposition of a dielectric material. An ALD process is used to deposit a layer of dielectric material, a metal that can be oxidized, an oxide material such as Ta₂O₅, Al₂O₃, or other vapor-phase dielectrics, e.g., Al₂O₃ at 380° C. using trimethylaluminum (TMA) and O₃ at a cycle time of 3.5 sec, and the Al₂O₃ layer is then heated in oxygen to 300° C. for 5 min to fully oxidize the dielectric layer. The thickness of this dielectric layer can range from 1 nm to 1000 nm, preferably 5 nm as can be seen in FIG. 2A. Next, a Resistor Inductor Diode (RLD), e.g., of copper, is deposited to fill the rectangular wells. The RLD is preferably a copper paste that is deposited by a silk-screening process. The substrate is then heated to 450° C. to 700° C. for 5 to 60 min in an inert gas or vacuum environment, preferably 600° C. for 20 min in argon gas. After the substrate with the RLD is heated as described, the RLD on the first surface of the substrate is made into rows and the RLD on the second surface is made into rows or columns. All of the rows on the first surface are tied together in parallel to make a first electrode for an RF power-conditioning capacitor with a large integrated surface area. Similarly, all of the rows or columns on the second surface are tied together in parallel to make a second electrode for this RF power-conditioning capacitor. FIG. 2B shows a view of to first surface the substrate in which the capacitive device has been made.

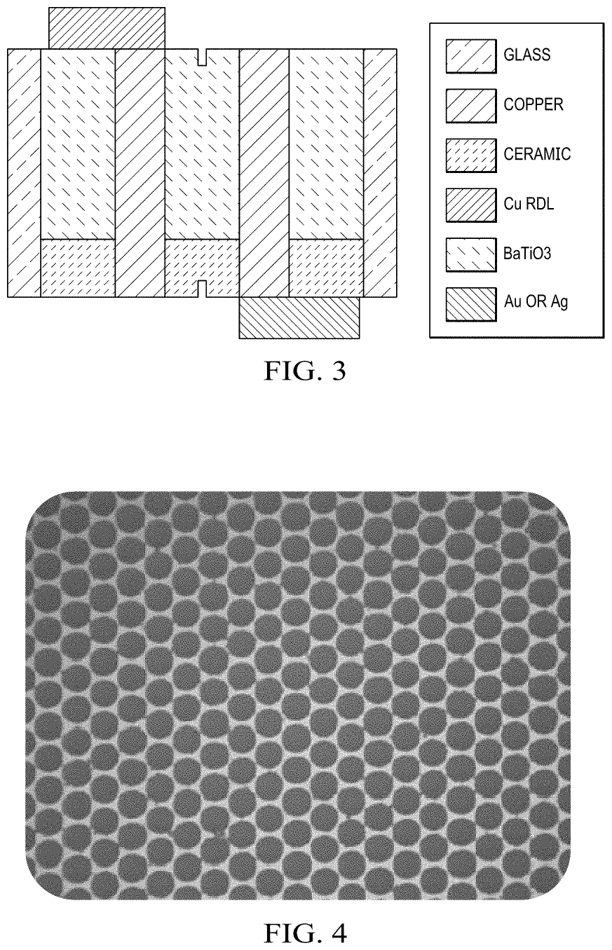

Another embodiment can be seen in FIG. 3. This embodiment includes one or more two- or three-dimensional capacitive devices created with one or more metal columns in a photodefinable glass substrate. The photodefinable glass substrate is then patterned with a pattern and etched through the volume of the substrate. The pattern may be rectangular, circular, elliptical, fractal, or of other shapes that provide capacitance. A uniform metallized seed layer, preferably including titanium, is deposited across the substrate, including the vias, by a CVD process. The seed-layer thickness can range from 50 nm to 1000 nm but is preferably 150 nm. The substrate is then placed into an electroplating bath where copper (Cu) is deposited on the seed layer. The copper layer needs to be sufficiently thick to fill the vias, in this case 25 μm. The copper layer and the seed layer are then removed from a first surface and a second surface of the wafer, e.g., by lapping and polishing or both, back to the photodefinable glass substrate. This can be seen in FIG. 2A. One or more rectangular wells are made in the first and second surfaces of the photodefinable glass substrate using the process described herein to convert 10% to 90% of the volume of the substrate, preferably 80%, to a crystalline ceramic and to etch these crystalline ceramic volumes away. The vias may also receive an additional low-concentration rinse with an etchant such as dilute HF. The low-concentration rinse will pattern or texture the ceramic walls of the vias. The patterning or texturing of the ceramic walls significantly increases the surface area of the one or more capacitive devices, directly increasing the capacitance of the devices. Next, the second surface of the photodefinable glass substrate with the one or more exposed copper columns is placed in contact with a metalized polyimide. The photodefinable glass substrate with the exposed copper columns contacted with the metalized polyimide is placed into an electroplating bath where a flash coating of non-oxidizing metal or a metal that forms a semiconductor oxide or a conductive oxide is electroplated on the surfaces of the copper columns. The metal electroplated on the surfaces of the copper columns is preferably gold (Au). This flash coating prevents the oxidation of the copper columns during the deposition of a dielectric material. This dielectric material includes commercially available BaTiO₃ paste, which is silk-screened into the rectangular wells. The substrate with the dielectric material is then heated to 450° C. to 700° C. for 5 to 60 min in an oxygen environment, preferably 600° C. for 30 min in an oxygen environment. After the substrate with the RLD is heated as described, the RLD on the first surface of the substrate is made into rows and the RLD on the second surface is made into rows or columns. All of the rows on the first surface are tied together in parallel to make a first electrode for an RF power conditioning capacitor with a large integrated surface area. Similarly, all of the rows or columns on the second surface are tied together in parallel to make a second electrode for this RF power conditioning capacitor.

FIG. 4 shows a through-hole via with a 65 μm diameter and a 72 μm center-to-center pitch.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

The present invention includes one or more two- or three-dimensional capacitive device structures or devices and methods of making such structures or devices.

An embodiment of a method of making a capacitive device described herein comprises, consists essentially of, or consists of providing a photodefinable glass substrate; processing the photodefinable glass substrate to form one or more vias; rinsing the one or more vias with an etchant to pattern or texture walls of the one or more vias, increasing the surface areas of the walls; depositing a metallized seed layer on the photodefinable glass substrate, wherein the metallized seed layer is deposited in the one or more vias; depositing a copper layer on the seed layer, wherein the copper layer is deposited in the one or more vias; exposing the photodefinable glass substrate by removing the seed layer and the copper layer from a first surface of the photodefinable glass substrate and from a second surface of the photodefinable glass substrate, leaving the seed layer and the copper layer in the one or more vias; making one or more rectangular wells in each of the first surface and the second surface around the one or more vias, exposing the copper layer in the one or more vias as copper columns; electroplating a flash coating of (1) a non-oxidizing metal, (2) a first metal that forms a semiconductor oxide or (3) a second metal that forms a conductive oxide on the first surface and the second surface of the photodefinable glass substrate; depositing a dielectric material on the front surface and the back surface of the photodefinable glass substrate; filling the one or more rectangular wells with an RLD; heating the photodefinable glass substrate; forming the RLD on the first surface of the photodefinable glass substrate into rows and tying the rows together in parallel to form a first capacitor electrode; and forming the RLD on the second surface of the photodefinable glass substrate into rows or columns and tying the rows or columns together in parallel to form a second capacitor electrode. In one aspect of this method, the step of depositing the metallized seed layer on the photodefinable glass substrate is performed with a chemical vapor deposition process. In another aspect, the metalized seed layer includes titanium. In another aspect, a thickness of the metalized seed layer is greater than 50 nm and less than 1000 nm. In another aspect, a thickness of the metalized seed layer is 150 nm. In another aspect, the step of depositing the copper layer on the metalized seed layer is performed by placing the photodefinable glass substrate in an electroplating bath. In another aspect, a thickness of the copper layer is 25 μm. In another aspect, the step of exposing the photodefinable glass substrate by removing the seed layer and the copper layer is performed by lapping, by polishing, or by both lapping and polishing. In another aspect, the step of making one or more rectangular wells in each of the first surface and the second surface around the one or more vias includes: converting one or more portions of the photodefinable glass substrate to a crystalline ceramic; and etching the crystalline ceramic away. In another aspect, this method further includes contacting the back surface of the photodefinable glass substrate, including the copper layer left in the one or more vias, with a metalized polyimide, performed after the step of making one or more rectangular wells and before the step of electroplating a flash coating on the front surface and the back surface of the photodefinable glass substrate. In another aspect, the step of electroplating a flash coating on the front surface and the back surface of the photodefinable glass substrate includes electroplating a flash coating of gold. In another aspect, the step of depositing the dielectric material is performed using atomic layer deposition. In another step, the dielectric material includes (1) a vapor-phase dielectric, (2) a paste, or (3) some combination. In another step, the dielectric material includes Ta₂O₅, Al₂O₃, a BaTiO₃ paste, or some combination. In another step, a thickness of the layer of dielectric material is greater than or equal to 1 nm and less than or equal to 1000 nm. In another aspect, a thickness of the layer of dielectric material is 5 nm. In another aspect, the RLD includes a copper paste. In another aspect, the step of depositing the RLD is performed by a process of silk-screening. In another aspect, the step of heating the photodefinable glass substrate includes heating to 450° C. to 700° C. for 5 to 60 minutes in an inert gas, vacuum environment, or oxygen environment.

One embodiment of a capacitive device described herein is made by a method that comprises, consists essentially of, or consists of providing a photodefinable glass substrate; processing the photodefinable glass substrate to form one or more vias; rinsing the one or more vias with an etchant to pattern or texture walls of the one or more vias, increasing the surface areas of the walls; depositing a metallized seed layer on the photodefinable glass substrate, wherein the metallized seed layer is deposited in the one or more vias; depositing a copper layer on the seed layer, wherein the copper layer is deposited in the one or more vias; exposing the photodefinable glass substrate by removing the seed layer and the copper layer from a first surface of the photodefinable glass substrate and from a second surface of the photodefinable glass substrate, leaving the seed layer and the copper layer in the one or more vias; making one or more rectangular wells in each of the first surface and the second surface around the one or more vias, exposing the copper layer in the one or more vias as copper columns; electroplating a flash coating of (1) a non-oxidizing metal, (2) a first metal that forms a semiconductor oxide or (3) a second metal that forms a conductive oxide on the first surface and the second surface of the photodefinable glass substrate; depositing a dielectric material on the front surface and the back surface of the photodefinable glass substrate; filling the one or more rectangular wells with an RLD; heating the photodefinable glass substrate; forming the RLD on the first surface of the photodefinable glass substrate into rows and tying the rows together in parallel to form a first capacitor electrode; and forming the RLD on the second surface of the photodefinable glass substrate into rows or columns and tying the rows or columns together in parallel to form a second capacitor electrode.

Another embodiment of a capacitive device described herein comprises, consists of, or consists of a first electrode including: one or more first copper columns each with patterned or textured surfaces to increase surface areas of the surfaces; and one or more rows of an RLD in contact with the one or more first copper columns, wherein the one or more rows of the RLD are tied together in parallel; a dielectric material in contact with the one or more first copper columns and in contact with the one or more rows of the RLD; and a second electrode including: one or more second copper columns each with patterned or textured surfaces to increase surface areas of the surfaces; and one or more rows or columns of the RLD in contact with the one or more second copper columns, wherein the one or more rows or columns of the RLD are tied together in parallel; wherein the capacitive device is in or on a photodefinable glass substrate. In one aspect of this capacitive device, a thickness of the copper layer is 25 μm. In another aspect, the dielectric material includes (1) a vapor-phase dielectric, (2) a paste, or (3) some combination. In another aspect, the dielectric material includes Ta₂O₅, Al₂O₃, a BaTiO₃ paste, or some combination. In another aspect, a thickness of the layer of dielectric material is greater than or equal to 1 nm and less than or equal to 1000 nm. In another aspect, a thickness of the layer of dielectric material is 5 nm. In another aspect, the RLD includes a copper paste.

While the making and using of various embodiments of the present invention are discussed in detail below, it should be appreciated that the present invention provides many applicable inventive concepts that can be embodied in a wide variety of specific contexts.

The specific embodiments discussed herein are merely illustrative of specific ways to make and use the invention and do not restrict the scope of the invention.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. A method of making a capacitive device comprising:
providing a photodefinable glass substrate;
processing the photodefinable glass substrate to form one or more vias;
rinsing the one or more vias with an etchant to pattern or texture walls of the one or more vias, increasing the surface areas of the walls;
depositing a metallized seed layer on the photodefinable glass substrate, wherein the metallized seed layer is deposited in the one or more vias;
depositing a copper layer on the seed layer, wherein the copper layer is deposited in the one or more vias;
exposing the photodefinable glass substrate by removing the seed layer and the copper layer from a first surface of the photodefinable glass substrate and from a second surface of the photodefinable glass substrate, leaving the seed layer and the copper layer in the one or more vias;
making one or more rectangular wells in each of the first surface and the second surface around the one or more vias, exposing the copper layer in the one or more vias as copper columns;
electroplating a flash coating of (1) a non-oxidizing metal, (2) a first metal that forms a semiconductor oxide or (3) a second metal that forms a conductive oxide on the first surface and the second surface of the photodefinable glass substrate;
depositing a dielectric material on the front surface and the back surface of the photodefinable glass substrate;
filling the one or more rectangular wells with a Resistor Inductor Diode (RLD);
heating the photodefinable glass substrate;
forming the RLD on the first surface of the photodefinable glass substrate into rows and tying the rows together in parallel to form a first capacitor electrode; and
forming the RLD on the second surface of the photodefinable glass substrate into rows or columns and tying the rows or columns together in parallel to form a second capacitor electrode. The method of claim 1, wherein the step of depositing the metallized seed layer on the photodefinable glass substrate is performed with a chemical vapor deposition process.

2. The method of claim 1, wherein the metalized seed layer comprises titanium.

3. The method of claim 1, wherein a thickness of the metalized seed layer is greater than 50 nm and less than 1000 nm.

4. The method of claim 1, wherein a thickness of the metalized seed layer is 150 nm.

5. The method of claim 1, wherein the step of depositing the copper layer on the metalized seed layer is performed by placing the photodefinable glass substrate in an electroplating bath.

6. The method of claim 1, wherein the step of exposing the photodefinable glass substrate by removing the seed layer and the copper layer is performed by lapping, by polishing, or by both lapping and polishing.

7. The method of claim 1, wherein the step of making one or more rectangular wells in each of the first surface and the second surface around the one or more vias comprises:
converting one or more portions of the photodefinable glass substrate to a crystalline ceramic; and
etching the crystalline ceramic away.

8. The method of claim 1, further comprising contacting the back surface of the photodefinable glass substrate, comprising the copper layer left in the one or more vias, with a metalized polyimide, performed after the step of making one or more rectangular wells and before the step of electroplating a flash coating on the front surface and the back surface of the photodefinable glass substrate.

9. The method of claim 1, wherein the step of electroplating a flash coating on the front surface and the back surface of the photodefinable glass substrate comprises electroplating a flash coating of gold.

10. The method of claim 1, wherein the step of depositing the dielectric material is performed using atomic layer deposition.

11. The method of claim 1, wherein the step of depositing the RLD is performed by a process of silk-screening.

12. The method of claim 1, wherein the step of heating the photodefinable glass substrate comprises heating to 450° C. to 700° C. for 5 to 60 minutes in an inert gas, vacuum environment, or oxygen environment.

13. A capacitive device made by the method of claim 1.

14. A capacitive device comprising:
a first electrode comprising:
one or more first copper columns each with patterned or textured surfaces to increase surface areas of the surfaces; and
one or more rows of a Resistor Inductor Diode (RLD) in contact with the one or more first copper columns, wherein the one or more rows of the RLD are tied together in parallel;
a dielectric material in contact with the one or more first copper columns and in contact with the one or more rows of the RLD; and
a second electrode comprising:
one or more second copper columns each with patterned or textured surfaces to increase surface areas of the surfaces; and
one or more rows or columns of the RLD in contact with the one or more second copper columns, wherein the one or more rows or columns of the RLD are tied together in parallel;
wherein the capacitive device is in or on a photodefinable glass substrate.

15. The capacitive device of claim 14, wherein a thickness of the copper layer is 25 μm.

16. The capacitive device of claim 14, wherein the dielectric material comprises (1) a vapor-phase dielectric, (2) a paste, or (3) some combination.

17. The capacitive device of claim 14, wherein the dielectric material comprises Ta₂O₅, Al₂O₃, a BaTiO₃ paste, or some combination.

18. The capacitive device of claim 14, wherein a thickness of the layer of dielectric material is greater than or equal to 1 nm and less than or equal to 1000 nm.

19. The capacitive device of claim 14, wherein a thickness of the layer of dielectric material is 5 nm.

20. The capacitive device of claim 14, wherein the RLD comprises a copper paste.
